(19) United States
(12) Patent Application Publication
(10) Pub. No.: US 2026/0209474 A1
(43) Pub. Date: Jul. 23, 2026

(54) POLYAMIDE COMPOSITION

(71) Applicant: BASF SE, Ludwigshafen am Rhein (DE)

(72) Inventors: Lin CHEN, Shanghai (CN); Yu Chen DAI, Shanghai (CN); Lu Ping ZHAO, Singapore (SG)

(21) Appl. No.: 19/135,936

(22) PCT Filed: Nov. 22, 2023
(86) PCT No.: PCT/EP2023/082651

§ 371 Date: Jun. 5, 2025

(30) Foreign Application Priority Data
Dec. 7, 2022 (WO) PCT/CN2022/137268

(51) Int. Cl. C08K 5/5313; C08K 3/22; C08K 3/26; C08K 5/5333; C08L 77/06; H10H 29/854

(52) U.S. Cl. CPC C08K 5/5313; C08K 3/22; C08K 3/26; C08K 5/5333; C08L 77/06; H10H 29/854; C08K 2003/2241; C08K 2003/265; C08L 2201/08

(57) ABSTRACT

The present invention relates to a polyamide composition, comprising 30 to 97% by weight of (A) at least one semi-crystalline semi-aromatic polyamide, 2 to 50% by weight of (B) at least one white pigment, 0.1 to 2% by weight of (C) at least a phosphorus containing thermal stabilizer, 0.1 to 4.5% by weight of (D) at least one alkali salt with pH higher than 7, and optionally 0 to 50% by weight of (E) at least one filler, based on the total weight of the polyamide composition. The present invention shows an excellent initial reflectivity and a small drop of reflectivity after thermal aging at high testing temperature for a long while. Also, it has been found that the polyamide composition keeps balanced mechanical properties. The present invention also relates to a LED component made from the polyamide composition. It can be manufactured or assembled by reflow soldering processes.

### FIELD OF THE INVENTION

The present invention relates to a polyamide composition for preparing LED components.

### BACKGROUND OF THE INVENTION

Plastic materials are widely used in areas where anti-yellowing is needed, such as out-door housing for consumer parts, automotive exterior parts, or a highly reflective application, more particularly in the manufacturing of light-emitting diode (LED) components. Among them, polyamide, especially semi-aromatic polyamide has been extensively used as a low cost and easily processing material to replace ceramics for LED components, such as housings, reflectors and reflector plates, where excellent heat resistance and high light reflectivity are desired. One problem that continuously puzzles the polyamide compositions used in LED applications is that they tend to get yellow when exposed to heat during manufacturing or under the environmental condition in use.

In recent years, surface mounting technology (SMT), which is basically a component assembly technology relating to producing electronic circuits in which the components are mounted or placed directly onto the surface of printed circuit boards (PCBs) using batch reflow soldering processes, has been rapidly developed. SMT has the advantages of miniaturization of electronic components, higher package density, efficiency of soldering process, reduced cost than the plated through-hole insertion process, which leads to the essential role of SMT in leading electronic products towards miniaturization and light weight. However, the disadvantage of SMT is that the processing temperature is higher than 250° C., which causes significant reflectivity decreases in LED applications.

U.S. Pat. No. 7,009,029 describes a high reflective thermoplastic polyphthalamide (PPA) molding composition comprising a white pigment titanium dioxide with a well-controlled particle size having an average particle size of 0.1 to 0.5 μm.

WO2013026779A describes a polyamide composition with improved reflectivity after heat aging by using an additive of metal oxide and titanium dioxide. When titanium dioxide is in an amount of 10-30 wt %, the effect is promising. The polyamide composition could also include filler, which is preferable in an amount of higher than 5 wt %. The reflectivity ratio is tested after 10 minutes at 260° C. However, aging time of 10 minutes can't fulfil the manufactory requirements.

CN105602243A describes a polyamide composition with a white pigment, a reinforcing filler, and a stabilizer package with elemental magnesium to elemental phosphorus. It was found that when the ratio of magnesium to phosphorus is controlled within the range of 0.1-1000, the initial whiteness of the polyamide composition could achieve 90 or more, and the whiteness can be kept at 80 or more after 4 hours aging at 180° C.

These improvements still not satisfying the practical application, especially when the aging temperature is very high such as the reflow soldering process (250° C. or higher) or the aging time is very long (500 h or longer). There is still some gap in term of anti-yellowing performance compared with traditional thermoset or ceramic material. Therefore, it's quite necessary and market valuable to develop a plastic composition with better reflectivity performance as molded and after thermal aging.

### SUMMARY OF THE INVENTION

The inventors of the present invention have made attempts to solve the above problem and found that a combination of a semi-aromatic polyamide, white pigments, a thermal stabilizer blend containing phosphorus compound and an inorganic or organic salt with pH value of higher than 7, shows an excellent initial reflectivity and a small drop of reflectivity after thermal aging at high testing temperature for a long while. Also, it has been found that the polyamide composition keeps balanced mechanical properties.

The present invention also provides a LED component made from the polyamide composition. It can be manufactured or assembled by reflow soldering processes.

### DETAILED DESCRIPTION OF THE INVENTION

Unless defined otherwise, all technical and scientific terms used herein have the meaning commonly understood by a person skilled in the art to which the invention belongs. The radical definitions or elucidations given above in general terms or within areas of preference apply to the end products and correspondingly to the starting materials and intermediates. These radical definitions can be combined with one another as desired, i.e., including combinations between the general definition and/or the respective ranges of preference and/or the embodiments.

All the embodiments and the preferred embodiments disclosed herein can be combined as desired, which are also regarded as being covered within the scope of the present invention.

The terms “a”, “an” and “the” are used interchangeable with the term “at least one”. The phrases “at least one of” and “comprises at least one of” followed by a list refers to any one of the items in the list and any combination of two or more item in the list. All numerical ranges are inclusive of their endpoints and non-integral values between the endpoints unless otherwise stated.

The term “about” refers to a range of numbers that a person of skill in the art would consider equivalent to the recited value in the context of achieving the same function or result.

Unless otherwise identified, all percentages (%) are “percent by weight”.

The term “unit” refers to a repeated unit constituting the polyamide, unless otherwise stated. As used herein, the term “PA” refers to polyamide. The term “PA*/PA**” refers to copolymer of PA* and PA**.

Disclosed is a polyamide composition for preparing LED components, comprising 30 to 97% by weight of (A) at least one semi-crystalline semi-aromatic polyamide, 2 to 50% by weight of (B) at least one white pigment, 0.1 to 2% by weight of (C) at least a phosphorus containing thermal stabilizer, 0.1 to 4.5% by weight of (D) at least one alkali salt with pH higher than 7, and optionally 0 to 50% by weight of (E) at least one filler, based on the total weight of the polyamide composition.

The term “semi-crystalline polyamide” is herein understood a semi-aromatic polyamide that has crystalline domains as demonstrated by the presence of a melting peek with a melting enthalpy of at least 5 J/g measured by differential scanning calorimetry (DSC) according to ISO11357 at a heating rate of 10K/min.

The semi-crystalline semi-aromatic polyamide in the present invention comprises dicarboxylic acid units, diamine units, and optionally units derived from other monomers such as amino acids and/or lactam units, the dicarboxylic acid units or diamine units having aromatic groups. For example, the semi-aromatic polyamide comprises aromatic dicarboxylic acid units and aliphatic diamine units, or aliphatic and/or cycloaliphatic dicarboxylic acid units and aromatic diamine units.

The aromatic dicarboxylic acid units can be typically derived from aromatic dicarboxylic acid and/or aromatic dicarboxylic acid chloride. The aliphatic dicarboxylic acid units can be typically derived from aliphatic dicarboxylic acid and/or aliphatic dicarboxylic acid chloride. The cycloaliphatic dicarboxylic acid units can be typically derived from cycloaliphatic dicarboxylic acid and/or cycloaliphatic dicarboxylic acid chloride.

The aliphatic or aromatic diamine units can be typically derived from aliphatic diamine or aromatic diamine respectively.

The other monomers are preferably in an amount of from 0 to 20 mol %, preferably from 0 to 15 mol %, more preferably from 0 to 10 mol %, based on the total units constituting the semi-crystalline semi-aromatic polyamide.

The aromatic dicarboxylic acid in the present invention preferably comprises from 8 to 20 carbon atoms, more preferably from 8 to 14 carbon atoms, such as terephthalic acid, isophthalic acid, naphthalene dicarboxylic acids and/or diphenyl dicarboxylic acids, more preferably is terephthalic, a mixture of terephthalic and isophthalic, naphthalene dicarboxylic acid, a mixture of terephthalic and naphthalene dicarboxylic acid.

The aliphatic dicarboxylic acid in the present invention preferably comprises from 4 to 36 carbon atoms, more preferably from 6 to 36 carbon atoms, most preferably from 6 to 20 carbon atoms or 36 carbon atoms, such as 6, 9, 10, 11, 12, 13, 14, 15, 16, 17, 18 and/or 36 carbon atoms. Examples of the aliphatic dicarboxylic acid are succinic acid, glutaric acid, adipic acid, pimelic acid, suberic acid, azelaic acid, sebacic acid, undecanedioic acid, dodecanedioic acid, tridecanedioic acid, tetradecanedioic acid, pentadecanoic acid, hexadecanedioic acid, octadecanedioic acid, dimer acid having 36 carbon atoms and mixtures thereof, more preferably is adipic acid, azelaic acid, sebacic acid, dodecanedioic acid and mixtures thereof.

The cycloaliphatic dicarboxylic acid in the present invention preferably comprises from 4 to 20 carbon numbers, more preferably from 8 to 20 carbon numbers, more preferably comprises one carbon backbone selected from the group consisting of cyclohexane, cyclopentane, cyclohexylmethane, dicyclohexylmethane, bis(methylcyclohexyl) and mixtures thereof, most preferably is selected from the group consisting of cis- and trans-cyclopentane-1,3-dicarboxylic acid, cis- and trans-cyclopentane-1,4-dicarboxylic acid, cis- and trans-cyclohexane-1,2-dicarboxylic acid, cis- and trans-cyclohexane-1,3-dicarboxylic acid, cis- and trans-cyclohexane-1,4-dicarboxylic acid and mixtures thereof.

The aliphatic diamine in the present invention could be linear aliphatic diamine or branched aliphatic diamine, preferably is linear aliphatic diamine. The aliphatic diamine preferably comprises from 4 to 36, more preferably from 6 to 22 carbon atoms or 36 carbon atoms, most preferably from 4 to 14 carbon atoms, such as 4, 6, 8, 9, 10, 11, 12, 13 and 14 carbon atoms. Examples of the linear aliphatic diamines are 1,4-butane diamine, 1,5-pentane diamine, 1,6-hexane diamine, 1,8-octanediamine, 1,9-nonanediamine, 1,10-decanediamine, 1,11-undecanediamine, 1,12-dodecanediamine, 1,13-tridecanediamine, 1,14-tetradecanediamine, 1,16-hexadecanediamine, 1,18-octadecanediamine, 1,20-eicosanediamine, 1,22-docosanediamine and mixtures thereof, preferably is 1,6-hexane diamine, 1,8-octanediamine, 1,9-nonanediamine, 1,10-decanediamine, 1,11-undecanediamine, 1,12-dodecanediamine and mixtures thereof, more preferably is 6-hexane diamine, 1,8-octanediamine, 1,9-nonanediamine, 1,10-decanediamine, 1,11-undecanediamine, 1,12-dodecanediamine and mixtures thereof. Examples of the branched aliphatic diamines are 2-methyl-1,5-pentane diamine, 3-methyl-1,5-pentane diamine, 2-methyl-1,8-octanediamine, 5-methyl-1,9-nonanediamine, 2,4,4-trimethylhexamethylene diamine, 2,2,4-trimethylhexamethylene diamine, 2,4-dimethyloctanediamine and mixtures thereof, preferably is 2-methyl-1,5-pentane diamine, 3-methyl-1,5-pentane diamine, 2-methyl-1,8-octanediamine, 2,4,4-trimethylhexamethylene diamine, 2,2,4-trimethylhexamethylene diamine and mixtures thereof.

The aromatic diamine in the present invention is preferably selected from the group consisting of m-xylylenediamine (MXD), p-xylylenediamine (PXD), bis(4-aminophenyl) methane, 3-methylbenzidine, 2,2-bis(4-aminophenyl) propane, 1,1-bis(4-aminophenyl)cyclohexane, 1,2-diaminobenzene, 1,3-diaminobenzene, 1,4-diaminobenzene, 1,2-diaminonaphthalene, 1,3-diaminonaphthalene, 1,4-diaminonaphthalene, 2,3-diaminotoluene, N,N′-dimethyl-4,4′-bephenyldiamine, bis(4-methylaminophenyl) methane, 2,2′-bis(4-methylaminophenyul) propane and mixtures thereof, more preferably is MXD and/or PXD.

The suitable amino acid in the present invention preferably comprises from 4 to 20 carbon atoms, more preferably from 4 to 14 carbon atoms, such as 9, 10, 11, 12 or 13 carbon atoms. Examples of the amino acid are 4-aminobutanoic acid, 6-aminocaproic acid, 7-aminoheptanoic acid, 8-aminooctanoic acid, 9-aminononanoic acid, 10-aminodecanoic acid, 11-aminoundecanoic acid, 12-aminododecanoic acid and mixtures thereof.

The suitable lactam in the present invention preferably comprises from 4 to 12 carbon atoms, more preferably from 6 to 12 carbon atoms. Examples of the lactam are 2-pyrrolidone (γ-butyrolactam), 2-piperidone (δ-valerolactam), ε-caprolactam, capryllactam, decanelactam, undecanolactam, enantholactam and/or lauryllactam, preferably is ε-caprlactam and/or undecanolactam.

In a preferred embodiment of the present invention, the semi-crystalline semi-aromatic polyamide comprises dicarboxylic acid units and diamine units, and 0 to 20 mol % of units derived from amino acids and/or lactams, based on the total mole of units constituting the semi-crystalline semi-aromatic polyamide;
i. wherein the dicarboxylic acid unit is derived from aromatic dicarboxylic acid and/or aromatic dicarboxylic acid chloride (a-1), or a combination of the aromatic dicarboxylic acid and/or aromatic dicarboxylic acid chloride (a-1) and the other dicarboxylic acid (a-2) including aliphatic dicarboxylic acid and/or cycloaliphatic dicarboxylic acid. The aromatic dicarboxylic acid and/or aromatic dicarboxylic acid chloride (a-1) is preferably in an amount of 60-100 mol %, the other dicarboxylic acid (a-2) is preferably in an amount of 0-40 mol %, based on the total mole of the dicarboxylic acid units constituting the semi-crystalline semi-aromatic polyamide;
the diamine unit is derived from aliphatic diamine (b-1), or a combination of aliphatic diamine (b-1) and aromatic diamine (b-2). The aliphatic diamine (b-1) is preferably in an amount of 80-100 mol %, the aromatic diamine (b-2) is preferably in an amount of 0-20 mol %, based on the total mole of the diamine units constituting the semi-crystalline semi-aromatic polyamide; or
ii. wherein the dicarboxylic acid unit is derived from aliphatic dicarboxylic acid or a combination of aliphatic dicarboxylic acid and cycloaliphatic dicarboxylic acid. The aliphatic dicarboxylic acid is preferably in an amount of 80-100 mol %, the cycloaliphatic dicarboxylic acid is preferably in an amount of 0-20 mol %, based on the total mole of the dicarboxylic acid units constituting the semi-crystalline semi-aromatic polyamide;
the diamine unit is derived from aromatic diamine, or a combination of aromatic diamine and aliphatic diamine. The aromatic diamine is preferably in an amount of 80-100 mol %, the aliphatic diamine is preferably in an amount of 0-20 mol %, based on the total mole of the diamine units constituting the semi-crystalline semi-aromatic polyamide.

In one preferred embodiment, the semi-crystalline semi-aromatic polyamide comprises dicarboxylic acid units and diamine units, wherein the dicarboxylic acid unit is derived from aromatic dicarboxylic acid and/or aromatic dicarboxylic acid chloride (a-1), or a combination of the aromatic dicarboxylic acid and/or aromatic dicarboxylic acid chloride (a-1) and the other dicarboxylic acid (a-2) including aliphatic dicarboxylic acid and/or cycloaliphatic dicarboxylic acid. The aromatic dicarboxylic acid (a-1) is terephthalic acid, naphthalene dicarboxylic acid, biphenyl dicarboxylic acid, a combination of terephthalic acid and isophthalic acid, or a combination of terephthalic acid and naphthalene dicarboxylic acid; the aromatic dicarboxylic acid and/or aromatic dicarboxylic acid chloride (a-1) is preferably in an amount of 60-100 mol %, more preferably 80-100 mol %, furthermore preferably 90-100 mol %, most preferably 95-100 mol %, based on the total mole of the dicarboxylic acid units constituting the semi-crystalline semi-aromatic polyamide; the other dicarboxylic acid (a-2) is preferably in an amount of 0-40 mol %, more preferably 0-20 mol %, furthermore preferably 0-10 mol %, most preferably is equal to or less than 5 mol %, based on the total mole of the dicarboxylic acid units constituting the semi-crystalline semi-aromatic polyamide;
the diamine unit is derived from aliphatic diamine (b-1), or a combination of aliphatic diamine and aromatic diamine (b-2). The aliphatic diamine (b-1) is preferably in an amount of 80-100 mol %, more preferably 90-100 mol %, most preferably 95-100 mol %, based on the total mole of the diamines constituting the semi-crystalline semi-aromatic polyamide; the aromatic diamine (b-2) is preferably in an amount of 0-20 mol %, more preferably is 0-10 mol %, most preferably is 0-5 mol %, based on the total mole of the diamine units constituting the semi-crystalline semi-aromatic polyamide.

In one preferred embodiment, the semi-crystalline semi-aromatic polyamide comprises dicarboxylic acid units and diamine units, the dicarboxylic acid unit is derived from aromatic dicarboxylic acid (a-1) and 0-10 mol %, more preferably 0-5 mol % of the other dicarboxylic acid (a-2), wherein the aromatic dicarboxylic acid (a-1) includes 10-40 mol %, more preferably 15-30 mol %, most preferably 20-30 mol % of isophthalic acid and 60-90 mol %, more preferably 70-85 mol %, most preferably 70-80 mol % of at least one aromatic dicarboxylic acid selected from the group consisting of terephthalic acid, naphthalene dicarboxylic acid and biphenyl dicarboxylic acid, preferably is terephthalic acid or a combination of terephthalic acid and naphthalene dicarboxylic acid; the other dicarboxylic acid is (a-2) is aliphatic dicarboxylic acid and/or cycloaliphatic dicarboxylic acid; the mole percentage is based on the total mole of the dicarboxylic acid units constituting the semi-crystalline semi-aromatic polyamide;
the diamine unit is derived from aliphatic diamine (b-1), or a combination of aliphatic diamine and aromatic diamine (b-2). The aliphatic diamine (b-1) is preferably in an amount of equal to or 90-100 mol %, more preferably 95-100 mol %; the aromatic diamine (b-2) is preferably in an amount of 0-10 mol %, more preferably 0-5 mol %, based on the total mole of the diamine units constituting the semi-crystalline semi-aromatic polyamide.

In one more preferred embodiment, the aliphatic dicarboxylic acid of the other dicarboxylic acid (a-2) is preferably adipic acid, suberic acid, azelaic acid, sebacic acid, undecanedioic acid, dodecanedioic acid, tridecanedioic acid, tetradecanedioic acid, pentadecanoic acid, hexadecanedioic acid, and octadecanedioic acid, more preferably is adipic acid, sebacic acid and/or dodecanedioic acid.

In one more preferred embodiment, the aliphatic diamine (b-1) is a linear aliphatic diamine (b-1a) or the combination of a linear aliphatic diamine and a branched aliphatic diamine (b-1b).

The linear aliphatic diamine (b-1a) is preferably selected from the group consisting of 1,4-butane diamine, 1,5-pentane diamine, 1,6-hexane diamine, 1,8-octanediamine, 1,9-nonanediamine, 1,10-decanediamine, 1,11-undecanediamine and 1,12-dodecanediamine. The branched aliphatic diamine (b-1b) is preferably selected from the group consisting of 2-methyl-1,5-pentane diamine, 3-methyl-1,5-pentane diamine, 2-methyl-1,8-octanediamine, 2,4,4-trimethylhexamethylene diamine and 2,2,4-trimethylhexamethylene diamine.

Examples of the semi-crystalline semi-aromatic polyamide is polyamide MXD6, polyamide PXD6, polyamide MXD9, polyamide PXD9, polyamide MXD10 and/or polyamide PXD10.

The polyamide in the present invention could comprise a polyamide copolymer or a blend of two or more polyamide and its copolymer.

The semi-crystalline semi-aromatic polyamide is suitably represented by the notations,
R represents one or more of linear aliphatic diamine and branched aliphatic diamine,
T represents terephthalic acid,
I represents isophthalic acid,
A represents one or more of aromatic diamine,
Y represents one or more of aliphatic dicarboxylic acid,
V represent one or more of lactam.

The suitable semi-crystalline semi-aromatic polyamide could be represented by PA RT, PA RT/RI, PA RT/BT, PA RT/BT/RI/BI, which comprising:
60-100 mol % of (T), 0-40 mol % of (I), preferably 60-85 mol % of (T), 15-40 mol % of (I), furthermore preferably 65-80 mol % of (T), 20-35 mol % of (I); based on the total mole of (T)+ (I); and
100 mol % of (R), R is preferably the linear or branched aliphatic polyamide having from 4 to 36 carbon numbers, more preferably having from 6 to 18 carbon numbers.

The examples of these polyamides include PA 4T/4I, PA 4T/6I, PA 5T/5I, PA 6T, PA 6T/6I, PA 6T/8T, PA 6T/10T, PA 6T/10I, PA 9T, PA 10T, PA 12T, PA 10T/10I, PA 6T/9T, PA 6T/12T, PA 4T/6T/DT, PA 4T/10T/DT, PA 4T/4I/6T/6I/DT/DI, PA6T/12T/6I/12I PA 6T/10T/6I, PA 4T/6T/4I/6I, PA 5T/6T/5I/6I, PA 5T/4T/5I/4I, PA 4T/10T/5I/10I, PA 4T/6T/DT, PA 4T/10T/DT or PA4T/4I/6T/6I/DT/DI, preferably is PA6T, PA9T, PA10T, PA 6T/6I, PA 6T/10T, PA6T/12T, PA 6T/10T/6I, PA 6T/DT or PA 6T/DT/6I/DI. Herein D is 2-methylpenta-methylenediamine or 3-methyl-1,5-pentanedimine, or a mixture thereof, and D is in an amount of 0-20 mol %, preferably 0-10 mol % of the total mole of (R).

In one preferred embodiment, PA 6T/61 comprises 65-80 mol % of (T), 20-35 mol % of (I).

In one preferred embodiment, PA 6T/10T comprises 10-60 mol % of (6T), 40-90 mol % of (10T), preferably 10-40 mol % of (6T), 60-90 mol % of (10T).

In one preferred embodiment, PA 6T/10T/61 comprises 60-90 mol % of (6T), 5-40 mol % of (6I) and 5-45 mol % of (10T).

In one preferred embodiment, PA 6T/10T/6 comprises 60-85 mol % of (6T), 15-40 mol % of (10T), and 5-15 mol % of caprolactam.

The suitable semi-crystalline semi-aromatic polyamide could be represented by PA RT/RY, PA RT/V, PA RT/RI/RY or PA RT/RI/V, which comprising:
60-100 mol % of (T), 0-40 mol % of (I); 0-10 mol % of (V), preferably 0-5 mol % of (V); 0-80 mol % of (Y), preferably 0-60 mol % of (Y), more preferably 0-40 mol % of (Y); based on the total mole of (T)+(I)+(V)+(Y); R is preferably the linear aliphatic polyamide having from 9 to 36 carbon numbers, more preferably having from 9 to 18 carbon numbers. The examples of these polyamides include PA 6T/6, PA6T/12, PA 6T/6I/6, PA 6T/66, PA 5T/510, PA4T/410, PA 6T/610, PA 6T/612, PA 6T/1012, PA 9T/612, PA 9T/1012, PA 10T/106, PA 10T/612, PA 10T/1012, PA 6T/6I/66, PA 10T/12, PA 10T/11 and PA 6T/6I/12, preferably is PA 6T/6, PA 6T/610 or PA 6T/612.

In one preferred embodiment, PA RT/RY comprises 60-100 mol % of (T), 0-40 mol % of (Y), R is 1,6-hexane diamine, 1,9-nonanediamine, 1,10-decanediamine, Y is dodecanedioic acid.

The semi-crystalline semi-aromatic polyamide in the present invention has a melting temperature (Tm) of 250° C.-350° C., preferably 280° C.-320° C., most preferably 305° C.-315° C. The melting temperature is defined as a temperature corresponding to an endothermic peak in a differential scanning calorimetry (DSC) curve, which is obtained by DSC according to ISO11357 at a heating rate of 10 K/min.

The semi-crystalline semi-aromatic polyamide in the present invention preferably has the viscosity number of 50-150 ml/g, which is measured in sulfuric acid with a concentration of 96 wt % according to ISO307-2007 method.

In one preferred embodiment, the semi-crystalline semi-aromatic polyamide is selected from polyamide MXD6, polyamide 12T, polyamide 10T, polyamide 9T, polyamide 6T/66, polyamide 6T/DT, polyamide 66/6T/6I, polyamide 6T/6, polyamide 6T/61 copolymer, and mixtures thereof.

The semi-crystalline semi-aromatic polyamide can be produced using a conventionally known method such as a melt polymerization method or a solution polymerization method.

The semi-crystalline semi-aromatic polyamide disclosed herein should not be limited to the ones prepared from virgin crude oil monomers, and could be completely or at least partially biobased or derived from waste stream or recycling activities, i.e., the polyamide used in the present application can be based on renewable materials, secondary raw materials or recycled raw materials. For example, PA 6T/6, PA6T/12, PA 6T/6I/6, PA 6T/66, PA 6T/610, PA 6T/612, PA 6T/1012, PA 9T/612, PA 9T/1012, PA 10T/106, PA 10T/612, PA 10T/1012, PA 6T/6I/66, PA 10T/12, PA 10T/11 and PA 6T/6I/12, used as component (A) in the present application could be prepared or obtained or derived from monomers that obtained in a re-monomerisation processes.

The semi-crystalline semi-aromatic polyamide in the present invention is in an amount of from 30% to 97% by weight, preferably from 40% to 85% by weight, more preferably from 45% to 80% by weight, such as 45%, 50%, 55%, 60%, 65%, 70%, 75%, 80% by weight; based on the total weight of polyamide composition.

### White Pigment

The white pigment in the present invention is preferably titanium oxide, zinc oxide, zirconium oxide, tin oxide, aluminum oxide, silicon oxide, magnesium oxide, calcium oxide, antimony oxide, titanium hydroxide, zinc hydroxide, magnesium hydroxide, zirconium hydroxide, zinc sulfate, calcium sulfate, zinc sulfide, aluminum phosphate, magnesium carbonate and the mixtures thereof. Among the white pigments, titanium oxide is preferably.

The white pigment is not limited to the size or form, it can be in the form of particle, whisker or fiber, preferably is particle.

The white pigment can be surface treated through existing methods with a coupling agent, such as a silane coupling agent, titanium coupling agents, acrylic silane-based coupling agents, epoxysilane-based coupling agents and aminosilane-based coupling agents, such as vinyltriethoxysilane, polydimethylsiloxane, 2-aminopropyltriethoxysilane, 2-glycidoxypropyltriethoxysilane, and the like, and combinations thereof.

In one preferred embodiment, the white pigment is titanium oxide, which shows better light reflectivity and light stability. The particle diameter of titanium oxide is preferably 100-500 nm, more preferably is 200-400 nm. The titanium dioxide can also be treated by an inorganic surface treatment agent. The surface treatment for titanium oxide can improve the wettability with the polyamide. Examples of the inorganic surface treatment agent can be selected from the group consisting of alumina, silica, zirconia, sodium silicate, sodium aluminate, sodium aluminosilicate, zinc oxide, mica, and the like. The inorganic surface treatment agent may be used alone or in combinations thereof.

The white pigment in the present invention is preferably in an amount of from 2% to 50% by weight, more preferably from 10% to 50% by weight, further preferably from 20% to 50% by weight, and most preferably from 20% to 40% by weight, for example 20%, 25%, 30%, 35%, 40% by weight; based on the total weight of polyamide composition.

### Phosphorus Containing Thermal Stabilizer

The phosphorus containing thermal stabilizer is found to provide better optical property and heat resistance to the polyamide composition comparing to other thermal stabilizers. The phosphorus containing thermal stabilizer is selected from the group comprising, but not limited to, organic phosphinate, inorganic hypophosphite, organic phosphonate, inorganic phosphonate, organophosphite and the mixture thereof, organic phosphonate and organic phosphinate are preferably.

The organic phosphonate in the present invention is the metal salt or ammonium salt of phosphonic acid or the derivate thereof. The metal can be alkali metal, earth alkali metal and the other usual metal. The examples of the metal are sodium, potassium, lithium, magnesium, calcium, barium, aluminum, and the mixture thereof, preferably are sodium, potassium or magnesium. The derivate of phosphonic acid can be alkyl group or aryl substituted phosphonic acid. The alkyl group preferably has from 1 to 6 carbon atoms. The preferred phosphonic acid derivate is phenylphosphonate, diphenylphosphonate, ethylphosphonate and diethylphosphonate.

In one preferred embodiment, the organic phosphonate is selected from the group consisting of sodium phosphonate, potassium phosphonate, sodium phenylphosphonate, potassium phenylphosphonate, lithium phenylphosphonate, sodium ethylphosphonate, potassium ethylphosphonate and ammonium phosphonate.

The inorganic phosphonate in the present invention conforms to the following general formula: [(HO)PO₂]²⁻_{p/2} Kat or [(HO)₂PO]⁻ₚKat^{p+}, in which Kat is a p-valent cation, especially a cation of an alkali metal or alkaline earth metal, an ammonium cation and/or a cation of Fe, Zn or especially of Al, including the cations Al(OH) or Al(OH)₂, and p is 1, 2, 3 or 4. Preferably, the inorganic phosphonate is aluminum phosphite [Al(H₂PO₃)₃].

The inorganic hypophosphite in the present invention is the metal salt or ammonium salt of hypophosphite. The metal can be alkali metal, earth alkali metal and the other usual metal. The examples of the metal are sodium, potassium, lithium, magnesium, calcium, barium, aluminum, and the mixture thereof, preferably are sodium, potassium or magnesium.

In one preferred embodiment, the inorganic hypophosphite is selected from the group consisting of sodium hypophosphite, potassium hypophosphite, lithium hypophosphite, magnesium hypophosphite, calcium hypophosphite and ammonium hypophosphites.

The organic phosphinate in the present invention is a metal salt having the Formula I.

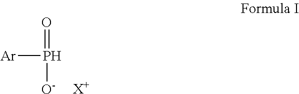

wherein Ar could be C₆ to C₁₈ aryl and X is a metal cation selected from Na, Ca, Mg, Al or Zn. The C₆ to C₁₈ aryl may be unsubstituted or substituted by a substituent such as C₁-C₁₀ alkyl, C₃-C₁₀ cycloalkyl, C₁-C₁₀ alkoxy, C₃-C₁₀ cycloalkoxy, C₁-C₁₀ alkylthio, C₃-C₁₀ cycloalkylthio, C₁-C₁₀ alkylamino, C₃-C₁₀ cycloalkylamine, C₆-C₁₈ aryl, C₆-C₁₈ aryloxy, C₆-C₁₈ arylthio, C₆-C₁₈ arylamino, halogen and the like, and combinations thereof. Preferably, the C₆ to C₁₈ aryl may be C₆ to C₁₆ aryl, preferably C₆ to C₁₄ aryl, more preferably C₆ to C₁₂ aryl, most preferably phenyl or naphthyl. Preferably, the phosphinate salt is sodium benzene phosphinate.

In one preferred embodiment of the present invention, the phosphorus containing thermal stabilizer is organic phosphinate and organic phosphonate, which further exhibit better anti-yellowing under high temperature and higher hydrolysis resistance.

In one preferred embodiment of the present invention, the organic phosphinate is sodium benzene phosphinate.

In one preferred embodiment of the present invention, the organic phosphonate is sodium phosphonate, and potassium phosphonate.

The phosphorus containing thermal stabilizer is not limited to the size. The preferred particular size is from 100 to 600 μm.

The phosphorus containing thermal stabilizer in the present invention is preferably in an amount of from 0.1% to 2% by weight, more preferably from 0.1% to 1% by weight, most preferably from 0.2 to 0.8% by weight, for example 0.2%, 0.3%, 0.4%, 0.5%, 0.6%, 0.7%, 0.8% by weight; based on the total weight of polyamide composition.

### Alkali Salt

Alkali salts in the present invention are also named as basic salt, which are salts that are the product of incomplete neutralization of a strong base and a weak acid. The alkali salt basically consists of an ionic assembly of positively charged cations and negatively charged anions, in which the cation is from the positively charged cation of a strong base, and the anion is from the negatively charged anion of a weak acid.

The strong base is a basic chemical compound that can remove a proton from a molecule of even a very weak acid in an acid base reaction. The strong bases are preferable hydroxide of alkali metal, earth alkali metal and ammonium salt, such as lithium hydroxide (LiOH), sodium hydroxide (NaOH), potassium hydroxide (KOH), rubidium hydroxide (RbOH), cesium hydroxide (CsOH), magnesium hydroxide (Mg(OH)₂), calcium hydroxide (Ca(OH)₂), strontium hydroxide (Sr(OH)₂), barium hydroxide (Ba(OH)₂), and tetramethylammonium hydroxide (N(CH₃)₄OH). Therefore, the positively charged cation of the alkali salt in the present invention can be selected from the group consisting of lithium-ion (Li⁺), sodium-ion (Na⁺), potassium-ion (K⁺), rubidium-ion (Rb), cesium-ion (Cs), magnesium-ion (Mg²⁺), calcium-ion (Ca²⁺), strontium-ion (Sr²⁺), barium-ion (Ba²⁺) and tetramethylammonium-ion (N(CH₃)₄⁺), preferably is earth metal ion such as magnesium-ion, calcium-ion and barium-ion, more preferably is calcium-ion and barium-ion.

The weak acid is the one that does not completely dissociate into their constituent ions when dissolved in solution. The weak acids are preferably inorganic weak acids and organic acid. Examples of inorganic weak acids are hydrofluoric acid (HF), nitrous acid (HNO₂), sulfurous acid (H₂SO₃), carbonic acid (H₂CO₃) and phosphoric acid (H₃PO₄). Examples of organic acids are formic acid (HCOOH), acetic acid (CH₃COOH), benzoic acid (C₆H₅COOH), citric acid (HOC(CO₂H)(CH₂CO₂H)₂), oxalic acid (C₂H₂O₄), acrylic acid (CH₂═CHCOOH) and phosphoric acid (H₃PO₄). The organic acids can also be in the form of polymer, such as polyacrylic acid with a weight-average molecular weight of about 3000-100000. When the organic acid is in the form of polymer, the molecular weight and synthetic method is not limited.

Therefore, the negative charged anions of the alkali salt in the present invention can be selected from the group consisting of formate (HCOO⁻), acetate (CH₃COO⁻), carbonate (CO₃²⁻), citrate (HOC(COO⁻) (CH₂COO⁻)₂), fluoride (F⁻), nitrite (NO₂⁻), benzoate (C₆H₅COO⁻), sulfite (SO₃²⁻), acrylate (CH₂═CHCOO⁻), dihydrogen phosphate ([H₂PO₄]⁻), hydrogen phosphate ([HPO₄]²⁻), and phosphate ([PO₄]³⁻).

The alkali salts in the present invention have the pH value higher than 7, which is defined and measured according to ISO 23496-2019.

In one preferred embodiment in the present invention, the alkali salts are selected from the group comprising, but not limited to, calcium carbonate, strontium carbonate, barium carbonate, sodium acrylate, calcium acrylate, potassium acrylate, sodium polyacrylate, calcium polyacrylate, potassium polyacrylate, sodium acetate, calcium acetate, barium acetate, potassium acetate, sodium citrate, calcium citrate, barium citrate, sulphite, hydrogen sulfate, silicate, meta-aluminate, phosphate and the mixture thereof.

In one preferred embodiment of the present invention, the alkali salts are calcium carbonate, barium carbonate, sodium polyacrylate, calcium polyacrylate and barium polyacrylate.

The particle size of the alkali salt is not limited, preferably is from 0.05 μm to 50 μm, and more preferably 0.1 μm to 10 μm.

Examples of calcium carbonate include calcite (calcite), aragonite (aragonite), natural calcium carbonate (heavy calcium carbonate), and synthetic calcium carbonate (precipitated calcium carbonate). Among them, calcite and aragonite are preferable.

It was surprisely found that alkali salt contributes a lot in the heat stability of the polyamide composition. Acid salt or neutral salt has no effect on heat stability improvement. Some alkali salts are also used as inorganic filler in polyamide composition. However, the amount of alkali salt in the present invention should be controlled in a specific range, when the amount is over 4.5%, the effect of heat stability increases unobvious and the mechanical properties of polyamide composition decreases rapidly.

The alkali salt in the present invention is preferably in an amount of from 0.1% to 4.5% by weight, more preferably from 0.5% to 4% by weight, most preferably is from 1% to 3% by weight; based on the total weight of polyamide composition.

The polyamide composition in the present invention can include from 0 to 50% by weight of fillers. The filler can be fibrous fillers, particular fillers and plate-like fillers.

The fibrous filler in the present invention are preferably selected from the group consisting of glass fibers, wollastonite, carbon fibers, metal fibers, mineral fibers, potassium titanate, aluminum borate, more preferably is glass fibers, milled glass fibers, chopped glass fibers, carbon fibers, potassium titanate and/or wollastonite.

Preferably, the glass fiber can be E-glass fibers, A-glass fibers, D-glass fibers, AR-glass fibers, C-glass fibers, S-glass fibers. The cross sections of the glass fiber can be round or non-circular, preferably is round.

The fibrous filler are preferably surface-treated by a silane coupling agent, such as vinylsilane-based coupling agents, acrylic silane-based coupling agents, epoxysilane-based coupling agents and aminosilane-based coupling agents, preferable is aminosilane-based coupling agents. The silane coupling agent may be dispersed in a sizing agent. Examples of the sizing agents are acrylic compounds, acrylic/maleic derivative modified compounds, epoxy compounds, urethane compounds, urethane/maleic derivative modified compounds and urethane/amine modified compounds.

The fibrous fillers in the polyamide composition preferably have an average length of 2-500 μm, preferably 200-300 μm, more preferably 220-240 μm. The diameter or major axis of the cross-section of the fibrous fillers are preferably 5-40 μm, preferably 10-25 μm.

Alternatively, the filler is used in the form of particles. The particular fillers may have a variety of particle sizes, ranging from particles in dust form to coarse particles. The particular fillers used may include organic or inorganic particles. Examples that can be used are inorganic particles such as kaolin, chalk, wollastonite, talc, silicates, graphite, mica, vermiculite, montmorillonite, glass particles (e.g., glass beads).

The filler in the present invention is preferably in an amount of from 10% to 50% by weight, more preferably from 10% to 30% by weight, most preferably is from 10% to 20% by weight; based on the total weight of polyamide composition.

The polyamide composition in the present invention can optionally comprise at least one additive (F), for example, lubricants, antioxidants, release agents, impact modifiers, compatibilizing agents, photostabilizers such as UV stabilizers, plasticizers, surfactants, nucleating agents, coupling agents, antimicrobial agents, antistatic agents, and any combinations thereof.

For the purpose of the present invention, the additives can be used in conventional amounts. For example, the polyamide composition can comprise at least one additive in an amount of 0.01 to 10% by weight, based on the total weight of the polyamide composition.

The polyamide composition can for example comprise an antioxidant. Suitable antioxidants are aromatic amine-based antioxidants, hindered phenol-based antioxidants and phosphite-based antioxidants, particularly hindered phenol-based antioxidants. Examples of hindered phenol-based antioxidants include, but are not limited to, α-[3-[3,5-bis(1,1-dimethylethyl)-4-hydroxyphenyl]-1-oxopropyl]-ω-[3-[3,5-bis(1,1-dimethylethyl)-4-hydroxyphenyl]-1-oxopropoxy]poly(oxy-1,2-ethanediyl), 2,4-bis[(octylthio)methyl]-o-cresol, octyl-3,5-di-tert-butyl-4-hydroxy-hydrocinnamate, 3,5-bis(1,1-dimethylethyl)-4-hydroxybenzenepropanoic acid C₇-C₉-branched alkyl ester, 2,4-bis[(dodecylthio)methyl]-o-cresol, 4,4′-butylidene bis-(3-methyl-6-tert-butylphenol), 3,5-bis(1,1-dimethylethyl)-4-hydroxybenzenepropanoic acid octadecyl ester, pentaerythritol tetrakis(3-(3,5-di-tert-butyl-4-hydroxyphenyl) propionate), triethylene glycol bis[3-(3-tert-butyl-5-methyl-4-hydrophenyl) propionate], 2,4-bis(n-octylthio)-6-(4-hydroxy-3,5-di-tert-butylanilino)-1,3,5-triazine, tris-(3,5-di-tert-butyl-4-hydroxybenzyl) isocyanurate, 2,2-thiodiethylene bis[3-(3,5-di-tert-butyl-4-hydroxyphenyl) propionate], N,N′-1,6-hexanediylbis[3,5-bis(1,1-dimethylethyl)-4-hydroxyl-benzenepropanamide.

The antioxidant, when present, can be in an amount of 0.01 to 1% by weight, or 0.1 to 0.5% by weight, based on the total weight of the polyamide composition.

The polyamide composition can for example comprise a lubricant. Suitable lubricant is preferably esters or amides of saturated or unsaturated aliphatic carboxylic acids having from 10 to 40, preferably from 16 to 22 carbon atoms with saturated aliphatic alcohols or amines which comprise from 2 to 40, preferably from 2 to 6 carbon atoms. The carboxylic acids can be mono- or dibasic. Examples of the carboxylic acids are pelargonic acid, palmitic acid, lauric acid, margaric acid, dodecanedioic acid, behenic acid, and particularly preferably stearic acid, capric acid, and also montanic acid (a mixture of fatty acids having from 30 to 40 carbon atoms). The aliphatic alcohols can be mono- to tetrahydric. Examples of the aliphatic alcohols are n-butanol, n-octanol, stearyl alcohol, ethylene glycol, propylene glycol, neopentyl glycol, and pentaerythritol, preference being given to glycerol and pentaerythritol. The aliphatic amines can be mono- to trifunctional. Examples of the aliphatic amines are stearylamine, ethylenediamine, propylenediamine, hexamethylenediamine, and di(6-aminohexyl) amine, particular preference being given here to ethylenediamine and hexamethylenediamine.

Preferred esters or amides are N,N′-ethylenedi (stearamide), glycerol distearate, glycerol tristearate, glycerol monopalmitate, glycerol trilaurate, glycerol monobehenate, and pentaerythritol tetrastearate. N,N′-ethylenedi (stearamide) is particularly preferred as a lubricant in the polyamide composition according to the present invention.

It is also possible to use mixtures of various esters or amides, or esters with amides in combination, in any desired mixing ratio.

The other lubricants are preferably long-chain fatty acids (e.g., stearic acid or behenic acid), salts of these (e.g., Ca stearate or Zn stearate), or montan waxes (mixtures of straight-chain, saturated carboxylic acids having chain lengths of from 28 to 32 carbon atoms), Ca montanate or Na montanate, and also low-molecular-weight polyethylene waxes and low-molecular-weight polypropylene waxes.

The lubricant, when present, can be in an amount of 0.01 to 2% by weight, or 0.2 to 1% by weight, based on the total weight of the polyamide composition.

The polyamide composition can for example comprise an impact modifier. Suitable impact modifiers can include polyolefin-based, styrene-based, unsaturated carboxylic acid-based impact modifiers. Suitable impact modifiers can also be those modified by a functional block, such as epoxy functional block and/or acid anhydride block. The epoxy function block can be units derived from a glycidyl (meth)acrylate. The acid anhydride block can be units derived from maleic anhydride.

Suitable polyolefin-based impact modifiers can include polyolefins comprising repeating units derived from olefin having 2 to 10 carbon atoms. Examples of such olefins include ethylene, 1-butene, 1-propylene, 1-pentene, 1-octene and mixture of ethylene and 1-octene, preferably ethylene, 1-propylene and mixture of ethylene and 1-octene.

Suitable unsaturated carboxylic acid-based impact modifiers can include blocks derived from carboxylic acid and derivates thereof such as ester, imide and amide. Suitable carboxylic acid and derivates thereof are for example acrylic acid, acrylic acid, methacrylic acid, maleic acid, fumaric acid, glutaconic acid, itaconic acid, citraconic acid, (meth)acrylate, methyl (meth)acrylate, ethyl (meth)acrylate, propyl (meth)acrylate, butyl (methyl) acrylate and isobutyl (meth)acrylate.

The impact modifier can also be a bi- or ter-polymer or a core-shell structure polymer. Examples of such impact modifier include styrene/ethylene/butylene copolymer (SEBS), ethylene-methyl acrylate-glycidyl methacrylate terpolymer, ethylene/propylene/diene rubber (EPDM) and ethylene-octene copolymer.

The impact modifier, when present, can be in an amount of 0.01 to 15% by weight, or 1 to 15% by weight, or 5 to 10% by weight, based on the total weight of the polyamide composition.

The polyamide composition can for example a plasticizer, including but are not limited to dioctyl phthalate, dibenzyl phthalate, butyl benzyl phthalate, hydrocarbon oils, and N-(n-butyl)benzenesulfonamide.

The plasticizer, when present, can be in an amount of 0.01 to 15% by weight, or 1 to 15% by weight, or 5 to 10% by weight, based on the total weight of the polyamide composition.

In a particular embodiment according to the present invention, the polyamide composition comprises:
30 to 97% by weight of (A) at least one semi-crystalline semi-aromatic polyamide,
2 to 50% by weight of (B) at least one white pigment which is selected from the group consisting of titanium oxide, zinc oxide, zirconium oxide, tin oxide, aluminum oxide, silicon oxide, magnesium oxide, calcium oxide, antimony oxide, titanium hydroxide, zinc hydroxide, magnesium hydroxide, zirconium hydroxide, zinc sulfate, calcium sulfate, zinc sulfide, aluminum phosphate, magnesium carbonate and the mixtures thereof,
0.1 to 2% by weight of (C) at least a phosphorus containing thermal stabilizer,
0.1 to 4.5% by weight of (D) at least one alkali salt with pH higher than 7, and optionally
0 to 50% by weight of (E) at least one filler,
each being based on the total weight of the polyamide composition.

In another preferred embodiment, the polyamide composition comprises:
30 to 97% by weight of (A) at least one semi-crystalline semi-aromatic polyamide,
2 to 50% by weight of (B) at least one white pigment which is selected from the group consisting of titanium oxide, zinc oxide, zirconium oxide, tin oxide, aluminum oxide, silicon oxide, magnesium oxide, calcium oxide, antimony oxide, titanium hydroxide, zinc hydroxide, magnesium hydroxide, zirconium hydroxide, zinc sulfate, calcium sulfate, zinc sulfide, aluminum phosphate, magnesium carbonate and the mixtures thereof,
0.1 to 2% by weight of (C) at least a phosphorus containing thermal stabilizer which is selected from the group consisting of organic phosphinate, inorganic hypophosphite, organic phosphonate, inorganic phosphonate, organophosphite and the mixture thereof,
0.1 to 4.5% by weight of (D) at least one alkali salt with pH higher than 7 which is selected from calcium carbonate, strontium carbonate, barium carbonate, sodium acrylate, calcium acrylate, potassium acrylate, sodium polyacrylate, calcium polyacrylate, potassium polyacrylate, sodium acetate, calcium acetate, barium acetate, potassium acetate, sodium citrate, calcium citrate, barium citrate, sulphite, hydrogen sulfate, silicate, meta-aluminate, phosphate and the mixture thereof, and optionally
0 to 50% by weight of (E) at least one filler,
each being based on the total weight of the polyamide composition.

In another preferred embodiment, the polyamide composition comprises:
30 to 97% by weight of (A) at least one semi-crystalline semi-aromatic polyamide,
2 to 50% by weight of (B) at least one white pigment which is selected from the group consisting of titanium oxide, zinc oxide, zirconium oxide, tin oxide, aluminum oxide, silicon oxide, magnesium oxide, calcium oxide, antimony oxide and the mixtures thereof,
0.1 to 2% by weight of (C) at least a phosphorus containing thermal stabilizer which is f organic phosphinate and/or organic phosphonate,
0.1 to 4.5% by weight of (D) at least one alkali salt with pH higher than 7 which is selected from calcium carbonate, strontium carbonate, barium carbonate, sodium polyacrylate, calcium polyacrylate, potassium polyacrylate and the mixture thereof, and optionally
0 to 50% by weight of (E) at least one filler,
each being based on the total weight of the polyamide composition.

In another preferred embodiment, the polyamide composition comprises:
47 to 67% by weight of (A) at least one semi-crystalline semi-aromatic polyamide,
30 to 50% by weight of (B) at least one white pigment which is selected from the group consisting of titanium oxide, zinc oxide, zirconium oxide, tin oxide, aluminum oxide, silicon oxide, magnesium oxide, calcium oxide, antimony oxide and the mixtures thereof,
0.5 to 1% by weight of (C) at least a phosphorus containing thermal stabilizer which is f organic phosphinate and/or organic phosphonate,
0.5 to 2% by weight of (D) at least one alkali salt with pH higher than 7 which is selected from calcium carbonate, strontium carbonate, barium carbonate, sodium polyacrylate, calcium polyacrylate, potassium polyacrylate and the mixture thereof, and optionally
0 to 50% by weight of (E) at least one filler,
each being based on the total weight of the polyamide composition.

The polyamide composition according to the present invention can be processed into various structures or forms by conventional methods to provide articles. For example, the individual components of the polyamide composition according to the present invention can be mixed and then molded, for example via injection and/or extrusion in conventional mixing apparatus, such as screw extruders, Brabender mixers or Banbury mixers to form the articles. The mixing temperatures used herein are generally from 220° C. to 260° C.

It will be understood that all components of the polyamide composition can be mixed at the same time. Alternatively, some components of the polyamide composition can be pre-mixed and then mixed with other components. For example, all starting components of the polyamide composition except the white pigment and filler are mixed together in a stirrer and fed into a twin-screw extruder at the throat, then the white pigment and filler are pre-mixed and fed at downstream using a side feeder.

Accordingly, the present invention provides a LED component made from the polyamide composition. It can be manufactured or assembled by reflow soldering processes.

The LED component is a part of a light-emitting diode reflector. Light-emitting diode arrangement is an assembly comprising at least one light-emitting semiconductor diode, a current source, and a housing covering the diode or a plate in which the diode is embedded. The LED component can be the housing or the plate of the light-emitting diode arrangement. The housing or plate can be fully or partially produced from the polyamide composition in the present invention. For example, one of walls of the housing is produced from the polyamide composition.

The LED component in the present invention can be the element of automobile light, mobile communication equipment, and household applications. The element of light includes instrumental panel displays of automobiles, screen of automobiles, turn signals, stop lights, interior and exterior lighting, floodlights, floor lights. The element of mobile electronic equipment includes displays of mobile phones, laptops, notebooks, e-book readers, tablet computers, pocket calculators, portable media players, mobile internet devices (MID), handheld PCs, handheld game consoles, digital media players, wearable computers such as a smart watch, head-mounted displays, virtual reality headsets, digital cameras, global positioning system receivers, portable power sources, portable Wi-Fis. The element of household applications includes the backlighting for TVs, liquid crystal displays, computer displays, laptop displays, notebook displays, displays of household applications, such as air-conditioners, intelligent housing system, mopping robots, electrical cookers, rice cookers, ovens, microwave ovens, washing machine, dish-washing machine, etc.

Accordingly, the present invention provides an article produced from the polyamide composition according to the present invention.

It is preferred that the articles according to the present invention have one or more of following properties,
a tensile stress at break of greater than 41 MPa measured according to ISO 527-1-2012.
a tensile strain at break of greater than 100% measured according to ISO 527-1-2012.
a tensile modulus of greater than 4450 MPa measured according to ISO 527-1-2012.
a Charpy notched impact strength at 23° C. of at least 1.8 KJ/m² measured according to ISO 179-1-2010.
a Charpy unnotched impact strength at 23° C. of at least 15 KJ/m² measured according to ISO 179-1-2010.
a heat deflection temperature of greater than 242° C. measured according to method A of ISO 75-2-2013 under 0.45 MPa.
a MVR of greater than 88 cm³/10 min measured according to ISO1133 under 325° C. and 2.16 kg loading.
a original reflectivity of greater than 96.1% measured at the wavelength of 460 nm.
a reflectivity drop of less than 4.4% measured after aging at 120° C. for 500 hours at the wavelength of 460 nm.
a reflectivity drop of less than 25.9% measured after aging at 260° C. for 30 minutes at the wavelength of 460 nm.

The reflectivity of the polyamide composition is well maintained especially after thermal aging at 260° C. for 30 minutes, which allows the polyamide composition can be used in reflow soldering processes and fulfil the application requirement of LED components.

### EXAMPLES

Aspects of the present invention are more fully illustrated by the following examples, which are set forth to illustrate certain aspects of the present invention and are not to be construed as limiting thereof.

Following materials and test methods were used in the Examples.

### Materials:

TABLE 1
The materials used in the inventive examples and comparative examples

| Acronym/Name | Description |
|---|---|
| A1: PA9T | Genestar ® GC51010 from |
| | Kuraray Co., Ltd., Tm = 305° C. |
| B1: TiO₂ | Titanium Dioxide Kronos 2220, |
| | available from Kronos |
| C1: Sodium | BRUGGOLEN ® H10 from |
| phosphonate | Bruggemann Chemical co |
| | Ltd. |
| C2: Sodium | Hangzhou Chemfar Co., Ltd |
| Benzene Phosphinate | |
| D1: Calcium Carbonate | Calcium Carbonate from |
| | Sinopharm >99% purity pH |
| | 8.0-10.5 (100 g/L, H₂O, 20° C.) |
| D2: Barium Carbonate | Barium Carbonate from |
| | Sinopharm >99% purity pH 7.5- |
| | 9.0 (0.016 g/L, H₂O, 16° C.) |
| D3: Sodium Polyacrylate | Sodium Polyacrylate from |
| | Sinopharm >95% purity pH |
| | 7.0-9.0 (10 g/L, H₂O, 20° C.) |
| | CAS No. 9003-04-7 |
| D4: MgCl₂ | Magnesium Chloride from |
| | Sinopharm >98% purity pH |
| | 4.5-7.0 (50 g/L, H2O, 20° C.) |
| D5: NaCl | Sodium Chloride from |
| | Sinopharm >98% purity PH ~7 |
| | (50 g/L, H₂O, 20° C.) |
| HALS | Hindered amine light |
| | stabilizers, Tinuvin 1600 from |
| | BASF |
| Oxide PE Wax | Lubricant, Luwax OA 5 |
| (CAS 68441-17-8) | from BASF |

### Measurements:

1. Tensile stress at break, tensile strain at break and tensile modulus for samples having thickness of 4 mm were measured according to ISO 527-1-2012. Test specimens of type 1 described in ISO 527-1-2012 were used. Charpy notched impact strength and Charpy unnotched impact strength was measured according to ISO 179-1-2010 via edgewise impact. The test specimens for Charpy unnotched test is type 1 specimen with the dimensions of 80*10*4 mm (length*width*thickness). The test specimens for Charpy notched test are type 1 with notched type A. All the test specimens were conditioned at 23° C. and 50% relative humidity for 16 h. The tests were conducted under the same atmosphere as conditioning.
2. Heat deflection temperature (HDT) was tested according to method A of ISO 75-2-2013 under 0.45 MPa.
3. Melt volume-flow rate (MVR) was tested according to ISO1133 under 325° C. and 2.16 kg loading.
4. The reflectivity related test was measure by a DC850 Spectrophotometer from Datacolor company with D65 light source reflection mode at the wavelength of 460 nm using a molded plastic plaque (60*60*2 mm) sample, according to CIE 1976.
   The test specimens used are made according to the following general procedure for preparing the test specimens.

### General Procedure for Preparing the Test Specimens

Test specimens were prepared in accordance with the formulations as shown in Table 2. All raw materials except the titanium dioxide (B) are mixed together in a Turbula T50A high-speed stirrer and fed into a ZE25Ax (Berstorff) twin-screw extruder at the throat, titanium dioxide are fed at downstream using a side feeder to keep good mechanical property. The raw materials are melt-extruded under a temperature of 320° C., pelletized, thus obtaining a polyamide composition in a pellet form.

Sample preparation and testing: The dried pellets were processed in an injection molding machine KM130CX, from Krauss Maffei with a clamping force of 130T at melt temperature of 320° C. and mold temperature of 120° C. to get test specimens.

The obtained test specimens were measured for the properties as described above. The test results and the formulations for the preparation of the test specimens are summarized in Table 2.

It can be seen from Table 2 that the inventive examples E1-E6 using a combination of phosphorus containing thermal stabilizer and alkali salt. The original reflectivities of E1 to E6 are higher than comparative examples C1-C3, and reflectivity drops after 500 h aging at 120° C. and 30 min aging at 260° C. of E1-E6 are prominantly lower than those of C1-C2, of which the reflectivity drops after 30 min aging at 260° C. are greater than 35%.

It will be apparent to one of ordinary skill in the art that various modifications and variations can be made in the present invention without departing from the scope or spirit of the present invention. It is intended that the embodiments and examples be considered as exemplary only. Thus, it is intended that the present invention covers such modifications and variations as come within the scope of the appended claims and their equivalents.

TABLE 2

| | E 1 | E2 | E3 | E4 | E5 | E6 | C1 | C2 | C3 | C4 | C5 | C6 |
|---|---|---|---|---|---|---|---|---|---|---|---|---|
| Component | | | | | | | | | | | | |
| A1 PA9T | 56.9 | 56.9 | 56.9 | 56.9 | 46.9 | 66.9 | 57.4 | 58.9 | 56.9 | 56.9 | 68.9 | 52.9 |
| B1 TiO₂ | 40 | 40 | 40 | 40 | 50 | 30 | 40 | 40 | 40 | 40 | 30 | 40 |
| C1: Sodium Phosphonate | | | | 0.5 | | | | | | | | |
| C2: Sodium Benzene | 0.5 | 0.5 | 0.5 | | 0.5 | 0.5 | | 0.5 | 0.5 | 0.5 | 0.5 | 0.5 |
| Phosphinate | | | | | | | | | | | | |
| D1: CaCO₃ | 2 | | | 2 | | | 2 | | | | | 6 |
| D2: BaCO₃ | | 2 | | | | | | | | | | |
| D3: Sodium Polyacrylate | | | 2 | | 2 | 2 | | | | | | |
| D4: MgCl₂ | | | | | | | | | 2 | | | |
| D5: NaCl | | | | | | | | | | 2 | | |
| HALS | 0.1 | 0.1 | 0.1 | 0.1 | 0.1 | 0.1 | 0.1 | 0.1 | 0.1 | 0.1 | 0.1 | 0.1 |
| Oxide PE Wax | 0.5 | 0.5 | 0.5 | 0.5 | 0.5 | 0.5 | 0.5 | 0.5 | 0.5 | 0.5 | 0.5 | 0.5 |
| Properties | | | | | | | | | | | | |
| MVR (cm³/10 min) | 103 | 88 | 135 | 102 | 112 | 124 | 96 | 127 | 142 | 102 | 133 | 152 |
| Tensile Modulus (MPa) | 4600 | 4550 | 4450 | 4500 | 5130 | 3640 | 4580 | 4350 | 4410 | 4330 | 3770 | 4510 |
| Tensile Stress (MPa) | 43 | 52 | 41 | 42 | 41 | 40 | 47 | 48 | 40 | 28 | 41 | 48 |
| Tensile Strain (%) | 1 | 1.2 | 1 | 1 | 0.8 | 1.1 | 1.1 | 1.1 | 0.8 | 0.6 | 1.1 | 1.2 |
| Charpy impact strength, | 1.8 | 1.9 | 1.7 | 2 | 2.6 | 1.8 | 1.9 | 1.9 | 1.7 | 1.9 | 2 | 3.3 |
| notched (KJ/m²) | | | | | | | | | | | | |
| Charpy impact strength, | 18 | 20 | 15 | 19 | 16 | 10 | 19 | 17 | 14 | 8 | 15 | 25 |
| unnotched (KJ/m²) | | | | | | | | | | | | |
| Heat deflection | 243 | 244 | 242 | 242 | 229 | 207 | 245 | 241 | 240 | 226 | 234 | 226 |
| temperature, 0.45 MPa (° C.) | | | | | | | | | | | | |
| Reflectivity, as casted % | 96.1 | 96.1 | 96.5 | 96.4 | 96.3 | 96.4 | 92.7 | 94.2 | 93.6 | 96.9 | 97.3 | 96 |
| Reflectivity drop after | 24.9 | 25.9 | 23.9 | 22.1 | 29.7 | 30.5 | 42.2 | 35.8 | 37.5 | 35.8 | 36.0 | 48.7 |
| 260° C. 30 min aging (%) | | | | | | | | | | | | |
| Reflectivity drop after | 3.1 | 3.7 | 3.4 | 4.4 | 4.4 | 5.7 | 9.2 | 6.9 | 5.3 | 4.7 | 6.7 | 5.9 |
| 120° C. 500 h aging (%) | | | | | | | | | | | | |

E: Inventive Example;
C: Comparative Example

1.-15. (canceled)

16. A polyamide composition for preparing LED components, comprising 30 to 97% by weight of (A) at least one semi-crystalline semi-aromatic polyamide, 2 to 50% by weight of (B) at least one white pigment, 0.1 to 2% by weight of (C) at least a phosphorus containing thermal stabilizer, 0.1 to 4.5% by weight of (D) at least one alkali salt with pH higher than 7, and optionally 0 to 50% by weight of (E) at least one filler, based on the total weight of the polyamide composition.

17. The polyamide composition according to claim 16, wherein the semi-crystalline semi-aromatic polyamide comprises dicarboxylic acid units and diamine units, and 0 to 20 mol % of units derived from amino acids and/or lactams, based on the total mole of units constituting the semi-crystalline semi-aromatic polyamide;
i. wherein the dicarboxylic acid unit is derived from aromatic dicarboxylic acid and/or aromatic dicarboxylic acid chloride (a-1), or a combination of the aromatic dicarboxylic acid and/or aromatic dicarboxylic acid chloride (a-1) and the other dicarboxylic acid (a-2) including aliphatic dicarboxylic acid and/or cycloaliphatic dicarboxylic acid, the aromatic dicarboxylic acid and/or aromatic dicarboxylic acid chloride (a-1) is in an amount of 60-100 mol %, the other dicarboxylic acid (a-2) is in an amount of 0-40 mol %, based on the total mole of the dicarboxylic acid units constituting the semi-crystalline semi-aromatic polyamide;
the diamine unit is derived from aliphatic diamine (b-1), or a combination of aliphatic diamine (b-1) and aromatic diamine (b-2), the aliphatic diamine (b-1) is in an amount of 80-100 mol %, the aromatic diamine (b-2) is in an amount of 0-20 mol %, based on the total mole of the diamine units constituting the semi-crystalline semi-aromatic polyamide; or
ii. wherein the dicarboxylic acid unit is derived from aliphatic dicarboxylic acid or a combination of aliphatic dicarboxylic acid and cycloaliphatic dicarboxylic acid, the aliphatic dicarboxylic acid is in an amount of 80-100 mol %, the cycloaliphatic dicarboxylic acid is in an amount of 0-20 mol %, based on the total mole of the dicarboxylic acid units constituting the semi-crystalline semi-aromatic polyamide;
the diamine unit is derived from aromatic diamine, or a combination of aromatic diamine and aliphatic diamine, the aromatic diamine is in an amount of 80-100 mol %, the aliphatic diamine is in an amount of 0-20 mol %, based on the total mole of the diamine units constituting the semi-crystalline semi-aromatic polyamide.

18. The polyamide composition according to claim 16, wherein the semi-crystalline semi-aromatic polyamide is selected from the group consisting of PA MXD6, PA PXD6, PA MXD9, PA PXD9, PA MXD10, PA PXD10, PA 4T/4I, PA 4T/6I, PA 5T/5I, PA 6T, PA 6T/6I, PA 6T/8T, PA 6T/10T, PA 6T/10I, PA 9T, PA 10T, PA 12T, PA 10T/10I, PA 6T/9T, PA 6T/12T, PA 4T/6T/DT, PA 4T/10T/DT, PA 4T/4I/6T/6I/DT/DI, PA6T/12T/6I/12I PA 6T/10T/6I, PA 4T/6T/4I/6I, PA 5T/6T/5I/6I, PA 5T/4T/5I/4I, PA 4T/10T/5I/10I, PA 4T/6T/DT, PA 4T/10T/DT or PA4T/4I/6T/6I/DT/DI, PA 6T/6, PA 6T/12, PA 6T/6I/6, PA 6T/66, PA 5T/510, PA4T/410, PA 6T/610, PA 6T/612, PA 6T/1012, PA 9T/612, PA 9T/1012, PA 10T/106, PA 10T/612, PA 10T/1012, PA 6T/6I/66, PA 10T/12, PA 10T/11 and PA 6T/6I/12.

19. The polyamide composition according to claim 16, wherein the white pigment is selected from the group consisting of titanium oxide, zinc oxide, zirconium oxide, tin oxide, aluminum oxide, silicon oxide, magnesium oxide, calcium oxide, antimony oxide, titanium hydroxide, zinc hydroxide, magnesium hydroxide, zirconium hydroxide, zinc sulfate, calcium sulfate, zinc sulfide, aluminum phosphate, magnesium carbonate and the mixtures thereof.

20. The polyamide composition according to claim 16, wherein the phosphorus containing thermal stabilizer is selected from organic phosphinate, inorganic hypophosphite, organic phosphonate, inorganic phosphonate, organophosphite and mixtures thereof.

21. The polyamide composition according to claim 20, wherein the organic phosphonate is selected from the group consisting of sodium phosphonate, disodium phosphonate, potassium phosphonate, sodium phenylphosphonate, potassium phenylphosphonate, lithium phenylphosphonate, sodium ethylphosphonate, potassium ethylphosphonate and ammonium phosphonate, the organic phosphinate is a metal salt having the Formula I, 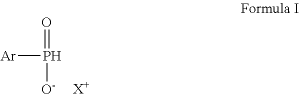
wherein Ar is C₆ to C₁₈ aryl and X is a metal cation selected from Na, Ca, Mg, Al or Zn, the C₆ to C₁₈ aryl is unsubstituted or substituted by a substituent of C₁-C₁₀ alkyl, C₃-C₁₀ cycloalkyl, C₁-C₁₀ alkoxy, C₃-C₁₀ cycloalkoxy, C₁-C₁₀ alkylthio, C₃-C₁₀ cycloalkylthio, C₁-C₁₀ alkylamino, C₃-C₁₀ cycloalkylamine, C₆-C₁₈ aryl, C₆-C₁₈ aryloxy, C₆-C₁₈ arylthio, C₆-C₁₈ arylamino, halogen and combinations thereof.

22. The polyamide composition according to claim 20, wherein the phosphorus containing thermal stabilizer is sodium benzene phosphinate, sodium phosphonate and/or potassium phosphonate.

23. The polyamide composition according to claim 16, wherein the alkali salts are selected from the group consisting of calcium carbonate, strontium carbonate, barium carbonate, sodium acrylate, calcium acrylate, potassium acrylate, sodium polyacrylate, calcium polyacrylate, potassium polyacrylate, sodium acetate, calcium acetate, barium acetate, potassium acetate, sodium citrate, calcium citrate, barium citrate, and mixtures thereof.

24. The polyamide composition according to claim 23, wherein the alkali salts are barium carbonate, sodium polyacrylate, calcium polyacrylate and barium polyacrylate.

25. The polyamide composition according to claim 23, wherein the alkali salts is calcium carbonate.

26. The polyamide composition according to claim 16, wherein the polyamide composition includes lubricants, antioxidants and/or photostabilizers.

27. The polyamide composition according to claim 16, wherein the polyamide composition comprises 45% to 80% by weight of component (A), 20% to 40% by weight of component (B), 0.1% to 2% of component (C), 0.5% to 4% of component (D), based on the total weight of the polyamide composition.

28. A LED component made from the polyamide composition according to claim 16.

29. The LED component according to claim 28, wherein the LED component is a housing or a plate of a light-emitting diode arrangement.

30. The LED component according to claim 28, wherein the LED component is the element of instrumental panel displays of automobiles, screen of automobiles, turn signals, stop lights, interior and exterior lighting, floodlights, floor lights, displays of mobile phones, laptops, notebooks, e-book readers, tablet computers, pocket calculators, portable media players, mobile internet devices, handheld PCs, handheld game consoles, digital media players, wearable computers, head-mounted displays, virtual reality headsets, digital cameras, global positioning system receivers, portable power sources, portable Wi-Fis, backlighting for TVs, liquid crystal displays, computer displays, laptop displays or notebook displays, displays of household applications.
